(19) United States
(12) Patent Application Publication
(10) Pub. No.: US 2010/0303114 A1
(43) Pub. Date: Dec. 2, 2010

(54) SEMICONDUCTOR LASER

(75) Inventor: Tomoyuki Kosugi, Miyagi (JP)

Correspondence Address: SNR DENTON US LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/775,079

(22) Filed: May 6, 2010

(30) Foreign Application Priority Data
May 27, 2009 (JP) 2009-127838

(51) Int. Cl. H01S 5/323

(52) U.S. Cl. 372/45.01

(57) ABSTRACT

The invention provides a semiconductor laser realizing reduction in an internal loss of light without thickening a cladding layer. The semiconductor laser includes a semiconductor layer on a semiconductor substrate. The semiconductor layer has, in order from the semiconductor substrate side, a lower cladding layer, an active layer, an upper cladding layer, and a contact layer, and has a first low-refractive-index layer having a refractive index lower than that of the upper cladding layer between the upper cladding layer and the contact layer.

### BACKGROUND OF THE INVENTION

1. Field of the Invention

The present invention relates to a semiconductor laser which is suitably used as, for example, a light source of a recording-type DVD (Digital Versatile Disk).

2. Description of the Related Art

Generally, for writing data to a high-density optical disk such as a recording-type DVD, an AlGaInP-based semiconductor laser is used. A laser for such use is requested to have, in addition to high output, stability at high temperatures, a low aspect ratio (θv (θ in the X axis direction)/θ_{H} (θ in the Y axis direction)), and the like.

In the semiconductor laser, to realize a low aspect ratio, light propagating in a light waveguide has to be widened to a ridge stripe side to a certain extent. A measure is therefore taken to widen the distribution of light to the ridge stripe side by replacing a part close to an active layer in a cladding layer on the ridge stripe side with a low-refractive-index layer. However, when the light distribution is widened too much, light is absorbed by a contact layer above the ridge stripe and the substrate. Another measure is therefore taken to reduce internal loss of light by thickening the cladding layer to keep the contact layer and the substrate far away from the active layer. By introducing a low-refractive-index layer near the active layer, the band gap of the part increases and carrier overflow is reduced, so that stability at high temperatures is also obtained.

An AlGaInP-based semiconductor laser is described in, for example, Japanese Unexamined Patent Application Publication Nos. 2005-333129, 2005-19467, and 2008-78340 and the like. A technique of replacing a part near the active layer in the cladding layer with a low-refractive-index layer having a refractive index lower than that of the cladding layer is described in, for example, Japanese Unexamined Patent Application Publication Nos. 2005-333129, 2008-219051, and 2008-34886 and the like.

### SUMMARY OF THE INVENTION

When the cladding layer is thickened to reduce the internal loss of light, an issue occurs such that thermal conductivity deteriorates and, in addition, growth time in a manufacturing time becomes longer, and productivity also deteriorates.

It is desirable to provide a semiconductor laser realizing reduced internal loss of light without thickening a cladding layer.

A first semiconductor laser according to an embodiment of the present invention has a semiconductor layer on a semiconductor substrate. The semiconductor layer has, in order from the semiconductor substrate side, a lower cladding layer, an active layer, an upper cladding layer, and a contact layer, and has a first low-refractive-index layer having a refractive index lower than that of the upper cladding layer between the upper cladding layer and the contact layer. The first low-refractive-index layer may be in contact directly with the contact layer or in contact with a semiconductor layer made of the same material as that of the upper cladding layer and thinner than the upper cladding layer in between.

In the first semiconductor laser according to an embodiment of the invention, the first low-refractive-index layer having a refractive index lower than that of the upper cladding layer is provided between the upper cladding layer and the contact layer. With the configuration, extension of the distribution of light to the contact layer may be suppressed by the first low-refractive-index layer.

A second semiconductor laser according to an embodiment of the invention has a semiconductor layer on a semiconductor substrate. The semiconductor layer has, in order from the semiconductor substrate side, a lower cladding layer, an active layer, an upper cladding layer, and a contact layer, and has a second low-refractive-index layer having a refractive index lower than that of the lower cladding layer between the lower cladding layer and the semiconductor substrate. The second low-refractive-index layer may be in contact directly with the semiconductor substrate or in contact with a semiconductor layer made of the same material as that of the lower cladding layer and thinner than the lower cladding layer in between.

In the second semiconductor laser according to an embodiment of the invention, the second low-refractive-index layer having a refractive index lower than that of the lower cladding layer is provided between the lower cladding layer and the semiconductor substrate. With the configuration, extension of the distribution of light to the semiconductor substrate may be suppressed by the second low-refractive-index layer.

In the first semiconductor laser according to an embodiment of the invention, extension of the distribution of light to the contact layer is suppressed by the first low-refractive-index layer. Consequently, light absorption in the contact layer may be reduced. With the configuration, without thickening the upper cladding layer, the internal loss of light may be reduced.

In the second semiconductor laser according to an embodiment of the invention, extension of the distribution of light to the semiconductor substrate is suppressed by the second low-refractive-index layer, so that light absorption in the semiconductor substrate may be reduced. With the configuration, without thickening the lower cladding layer, the internal loss of light may be reduced.

Other and further objects, features and advantages of the invention will appear more fully from the following description.

### BRIEF DESCRIPTION OF THE DRAWINGS

FIG. 1 is a cross section of a semiconductor laser according to a first embodiment of the invention.

FIG. 2 is a diagram illustrating lineup of conduction bands of the semiconductor laser of FIG. 1.

FIG. 3 is a relation diagram illustrating the relation between thickness of a low-refractive-index layer of FIG. 1 and light loss.

FIG. 4 is a relation diagram illustrating the relation between thickness of a second p-type cladding layer of FIG. 1 and light loss.

FIG. 5 is a diagram of lineup of conduction bands as a modification of the semiconductor laser of FIG. 1.

FIG. 6 is a cross section of another modification of the semiconductor laser of FIG. 1.

FIG. 7 is a diagram illustrating lineup of conduction bands of the semiconductor laser of FIG. 6.

FIG. 8 is a cross section of a semiconductor laser according to a second embodiment of the invention.

FIG. 9 is a diagram illustrating lineup of conduction bands of the semiconductor laser of FIG. 8.

### DETAILED DESCRIPTION OF THE PREFERRED EMBODIMENTS

Modes for carrying out the invention will be described in detail below with reference to the drawings. The description will be given in the following order.

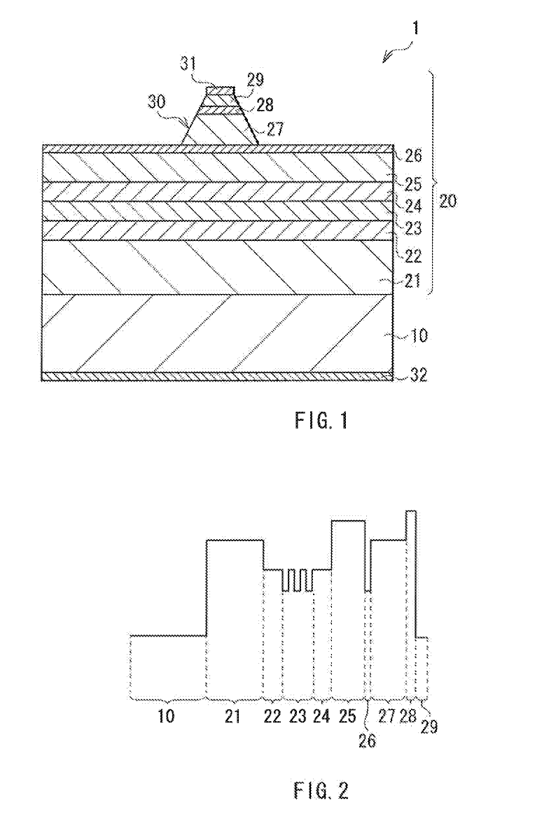

1. First embodiment (an example in which a low-refractive-index layer is provided on the p side, FIGS. 1 and 2)

Modification (an example in which energy distributions of the valence band are different, FIG. 5)

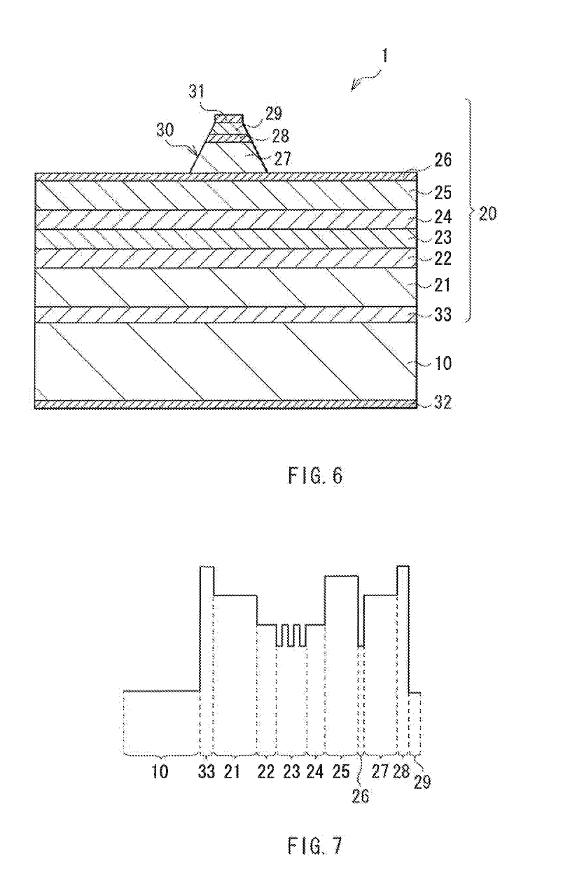

Modification (an example in which the low-refractive-index layer is provided also on the n side, FIGS. 6 and 7)

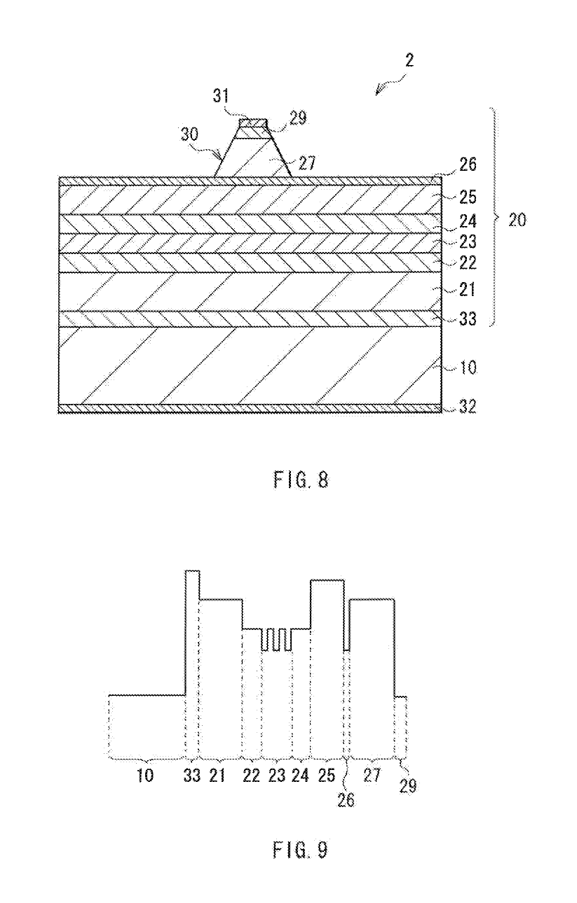

2. Second embodiment (an example in which the low-refractive-index layer is provided on the n side, FIGS. 8 and 9)

### First Embodiment

FIG. 1 illustrates an example of a sectional configuration of a semiconductor laser 1 according to a first embodiment of the invention. FIG. 2 illustrates an example of lineup of conduction bands of the semiconductor laser 1 of FIG. 1. The semiconductor laser 1 of the embodiment is, for example, an edge-emitting type semiconductor laser capable of emitting, for example, light in the 600 nm band (for example, 650 nm) for a high-density optical disc such as a recording-type DVD from an end face (not illustrated). The semiconductor laser 1 has, for example, a semiconductor layer 20 on a substrate 10. The substrate 10 corresponds to a concrete example of a “semiconductor substrate” of the invention.

The substrate 10 is, for example, an n-type GaAs substrate. Examples of an n-type impurity are silicon (Si) and selenium (Se). The semiconductor layer 20 contains a quaternary III-V group compound semiconductor, for example, an AlGaInP-based compound semiconductor. “Quaternary” denotes mixed crystal of four kinds of elements, and a III-V group compound semiconductor denotes a compound semiconductor containing a III-group element and a V-group element. The AlGaInP-based compound semiconductor denotes a compound semiconductor containing total four kinds of elements of Al, Ga, In, and P.

The semiconductor layer 20 is obtained by, for example, making crystal grown on the substrate 10. The semiconductor layer 20 includes, in order from the substrate 10 side, for example, an n-type cladding layer 21, an n-side guide layer 22, an active layer 23, a p-side guide layer 24, a first p-type cladding layer 25, an etching stop layer 26, a second p-type cladding layer 27, a low-refractive-index layer 28, and a contact layer 29. The low-refractive-index layer 28 may be in direct contact with the contact layer 29, or in contact with a semiconductor layer made of the same material as that of the second p-type cladding layer 27 and thinner than the second p-type cladding layer 27 in between.

The n-type cladding layer 21 corresponds to a concrete example of a “lower cladding layer” of the invention. The first p-type cladding layer 25 and the second p-type cladding layer 27 correspond to a concrete example of an “upper cladding layer” of the invention. The low-refractive-index layer 28 corresponds to a concrete example of a “first low-refractive-index layer” of the invention. The first p-type cladding layer 25 corresponds to a concrete example of a “first cladding layer” of the invention. The second p-type cladding layer 27 corresponds to a concrete example of a “second cladding layer” of the invention.

The forbidden band width of the n-type cladding layer 21 is larger than that of the n-side guide layer 22 and the active layer 23, and the refractive index of the n-type cladding layer 21 is smaller than that of the n-side guide layer 22 and the active layer 23. The lower end of the conduction band of the n-type cladding layer 21 is higher than that of the conduction band of the n-side guide layer 22 and the active layer 23. The n-type cladding layer 21 contains, for example, n-type (AlₑGa₁₋ₑ)_{f}In_{1-f}P (0<e<0.7, 0<f<1). Examples of the n-type impurity include silicon (Si) and selenium (Se).

The forbidden band width of the n-side guide layer 22 is larger than that of the active layer 23, and the refractive index of the n-side guide layer 22 is smaller than that of the active layer 23. The lower end of the conduction band of the n-side guide layer 22 is higher than that of the conduction band of the active layer 23. The n-side guide layer 22 contains, for example, undoped (AlᵢGa₁₋ᵢ)ₖIn₁₋ₖP (0<i<e, 0<k<1x).

In the specification, “undope” denotes a state that an impurity material is not supplied at the time of manufacturing a semiconductor layer as an object. Therefore, “undope” denotes a concept including the case where no impurity is contained in a semiconductor layer as an object and the case where an impurity diffused from another semiconductor layer is slightly contained.

The active layer 23 has a forbidden band width corresponding to a desired light emission wavelength (for example, wavelength in the 600 nm band). The active layer 23 has, for example, a multiple quantum well structure of a well layer and a barrier layer respectively made of undoped AlGaInP of compositions different from each other. A region facing a ridge 30 which will be described later in the active layer 23 is a light emission region (not illustrated). The light emission region has a stripe width equivalent to the bottom of the facing ridge 30 and corresponds to a current injection region to which current confined by the ridge 30 flows.

The forbidden band width of the p-side guide layer 24 is larger than that of the active layer 23, and the refractive index of the p-side guide layer 24 is smaller than that of the active layer 23. The upper end of a valence band of the p-side guide layer 24 is lower than that of the valence band of the active layer 23. The p-side guide layer 24 contains, for example, undoped (AlₘGa₁₋ₘ)ₙIn₁₋ₙP (0<m<p, 0<n<1) (p denotes Al composition ratio of the first p-type cladding layer 25).

The first p-type cladding layer 25 is provided on the active layer 23 side in the relation with the second p-type cladding layer 27. The forbidden band width of the first cladding layer 25 is larger than that of the active layer 23 and the p-side guide layer 24. The first p-type cladding layer 25 has a refractive index smaller than that of the active layer 23 and the p-side guide layer 24, and larger than that of the second p-type cladding layer 27. The upper end of the valance band of the first p-type cladding layer 25 is lower than that of the valence band of the active layer 23 and the p-side guide layer 24. In the embodiment, the forbidden band width of the first p-type cladding layer 25 is larger than that of the n-type cladding layer 21, and the refractive index of the first p-type cladding layer 25 is smaller than that of the n-type cladding layer 21. The first p-type cladding layer 25 contains, for example, p-type (AlₚGa₁₋ₚ)_{q}In_{1-q}P (0<p<0.7, 0<q<1). Examples of the p-type impurity include magnesium (Mg) and zinc (Zn).

The etching stop layer 26 is made of a material having etching rate lower than that of the second p-type cladding layer 27 for a predetermined etchant. The etching stop layer 26 contains, for example, p-type (Alᵣa₁₋ᵣ)ₛIn₁₋ₛP (0<r<m, 0<s<1).

The second p-type cladding layer 27 is provided on the contact layer 29 side (the low-refractive-index layer 28 side) in relation with the first p-type cladding layer 25. The forbidden band width of the second cladding layer 27 is larger than that of the active layer 23 and the p-side guide layer 24 and is smaller than that of the first p-type cladding layer 25. The second p-type cladding layer 27 has a refractive index smaller than that of the active layer 23 and the p-side guide layer 24, and larger than that of the first p-type cladding layer 25. The upper end of the valance band of the second p-type cladding layer 27 is lower than that of the valence band of the active layer 23 and the p-side guide layer 24, and higher than that of the valance band of the first p-type cladding layer 25. The second p-type cladding layer 27 contains, for example, p-type (AlₜGa₁₋ₜ)ᵤIn₁₋ᵤP (0<t<p, 0<u<1).

The low-refractive-index layer 28 is provided between the second p-type cladding layer 27 and the contact layer 29. The forbidden band width of the low-refractive-index layer 28 is larger than that of the active layer 23 and the p-side guide layer 24 and is larger than that of the first p-type cladding layer 25 and the second p-type cladding layer 27. The low-refractive-index layer 28 has a refractive index smaller than that of the active layer 23 and the p-side guide layer 24, and smaller than that of the first p-type cladding layer 25 and the second p-type cladding layer 27. The upper end of the valance band of the low-refractive-index layer 28 is lower than that of the valence band of the active layer 23 and the p-side guide layer 24, and lower than that of the valance band of the first p-type cladding layer 25 and the second p-type cladding layer 27. The low-refractive-index layer 28 contains, for example, p-type (Al_{c}Ga_{1-c})_{d}In_{1-d}P (0.7≦c≦1, 0<d<1).

The contact layer 29 is provided to make a p-side electrode 31 which will be described later and the second p-type cladding layer 27 (the low-refractive-index layer 28) come into ohmic-contact with each other. The contact layer 29 contains, for example, p-type GaAs.

In the embodiment, the stripe-shaped ridge 30 extending in one direction in the stack layer plane is formed in an upper part of the semiconductor layer 20. The ridge 30 includes, for example, as illustrated in FIG. 1, the second p-type cladding layer 27, the low-refractive-index layer 28, and the contact layer 29. The contact layer 29 is provided on the outermost layer of the ridge 30. Although FIG. 1 illustrates the case where only one ridge 30 is provided for the semiconductor layer 20, two or more ridges 30 may be provided.

In the semiconductor layer 20, a pair of end faces (not illustrated) sandwiching the ridge 30 from the extending direction of the ridge 30 are formed. By the end faces, a resonator is constructed. The pair of end faces is formed by, for example, cleavage and is disposed so as to face each other with a predetermined gap in between. Further, a low-reflection film (not illustrated) is formed on the end face (front end face) on the light emitting side out of the pair of end faces, and a high-reflection film (not illustrated) is formed on the end face (rear end face) on the side opposite to the light emitting side out of the pair of end faces.

The p-side electrode 31 is provided on the top face of the ridge 30 (the top face of the contact layer 29). The p-side electrode 31 has a band shape extending in the extending direction of the ridge 30, and is electrically connected to the contact layer 29. The p-side electrode 31 is constructed by, for example, stacking titanium (Ti), platinum (Pt), and gold (Au) in order from the substrate 10 side. An n-side electrode 32 is provided on the rear face of the substrate 10. The n-side electrode 32 is formed, for example, continuously in a region including the region facing the ridge 30 in the rear face of the substrate 10. The n-side electrode 32 is constructed by stacking, for example, an alloy of gold (Au) and germanium (Ge), nickel (Ni), and gold (Au) in order from the substrate 10 side and is electrically connected to the substrate 10.

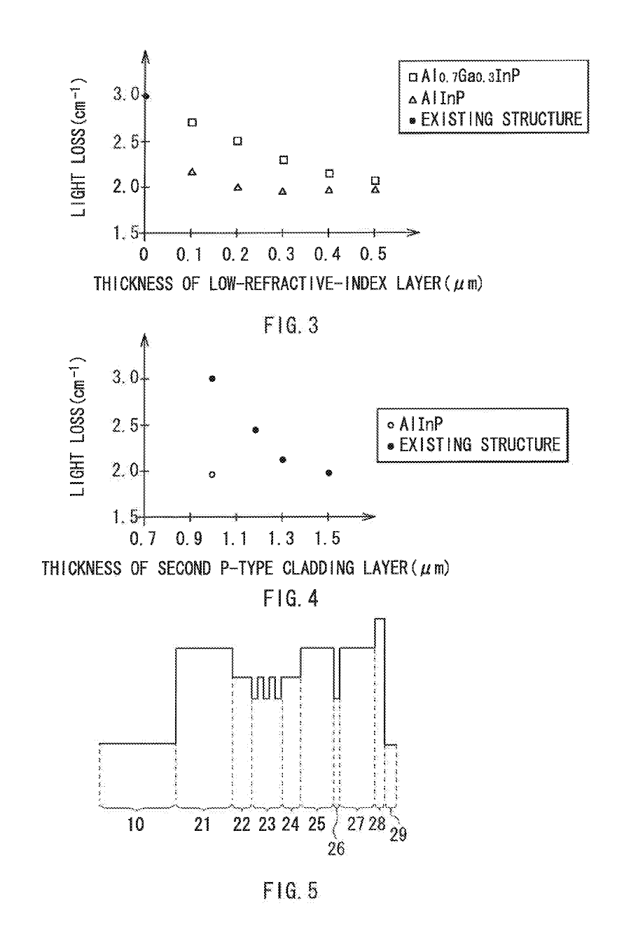

Next, the relation between thicknesses of the low-refractive-index layer 28 and the second p-type cladding layer 27 and light loss will be described. FIG. 3 expresses the relation between the thickness of the low-refractive-index layer 28 and the light loss. FIG. 4 expresses the relation between the thickness of the second p-type cladding layer 27 and the light loss. FIG. 3 illustrates a result when the thickness of the second p-type cladding layer 27 is set to 1.0 μm and the low-refractive-index layer 28 is made of AlInP or Al_{0.7}Ga_{0.3}InP. FIG. 4 illustrates a result when the thickness of the low-refractive-index layer 28 is set to 0.2 μm and the low-refractive-index layer 28 is made of AlInP. Further, results of the existing structure which is not provided with the low-refractive-index layer 28 are shown as a comparative example.

It is understood from FIG. 3 that, by providing the low-refractive-index layer 28, a light loss reduction effect is obtained. Further, it is also understood that the thickness of the low-refractive-index layer 28 is preferably 0.1 μm to 0.5 μm both inclusive. When the thickness of the low-refractive-index layer 28 becomes below 0.1 μm, the effect (light loss reduction effect) produced by providing the low-refractive-index layer 28 is very small, and it is meaningless in practice. On the other hand, when the thickness of the low-refractive-index layer 28 exceeds 0.5 μm, the light loss reduction effect is almost the same as that in the case where the thickness of the low-refractive-index layer 28 is 0.5 μm. Consequently, in this case, demerits such as deterioration in thermal conductivity and drop in production efficiency caused by increase in the thickness of the low-refractive-index layer 28 becomes conspicuous. There is no merit to increase the thickness of the low-refractive-index layer 28 more than 0.5 μm.

It is understood from FIG. 4 that the light loss may be suppressed sufficiently low by the light confinement effect of the low-refractive-index layer 28 without setting the thickness of the second p-type cladding layer 27 to the usual thickness. Therefore, by providing the low-refractive-index layer 28, without thickening the second p-type cladding layer 27, the light loss may be suppressed sufficiently low.

An example of a method of manufacturing the semiconductor laser 1 of the embodiment will now be described.

First, for example, by using the MOCVD (Metal Organic Chemical Vapor Deposition), the AlGaInP-based semiconductor layer 20 is epitaxially grown on the substrate 10. As the material of the AlGaInP-based compound semiconductor, for example, TMA (trimethylaluminum), TMG (trimethylgallium), TMIn (trimethylindium), or PH₃ (phosphine) is used. Concretely, on the substrate 10, the n-type cladding layer 21, the n-side guide layer 22, the active layer 23, the p-side guide layer 24, the first p-type cladding layer 25, the etching stop layer 26, the second p-type cladding layer 27, the low-refractive-index layer 28, and the contact layer 29 are formed in order from the substrate 10 side.

Next, a resist pattern in a predetermined shape is formed on the contact layer 29 by lithography to cover the stripe-shaped region in which the ridge 30 is to be formed. After that, for example, by using dry etching, the semiconductor layer 20 is selectively removed. By the operation, the ridge 30 is formed in the upper part of the semiconductor layer 20.

Next, a resist pattern covering a region other than the top face of the ridge 30 is formed and, then, for example, a Ti/Pt/Au multilayer film is stacked on the entire surface by vacuum deposition. After that, the resist pattern is removed together with the Ti/Pt/Au multilayer film deposited on the resist pattern by the lift-off method. In such a manner, the p-side electrode 31 is formed on the top face of the ridge 30. After that, heat treatment is performed as necessary, and ohmic contact is carried out. Subsequently, for example, by stacking a AuGe alloy/Ni/Au multilayer film (not illustrated) on the entire rear face of the substrate 10 by vacuum deposition, the n-side electrode 32 is formed.

Next, for example, an end part of the wafer is scratched with a cutter, and pressure is applied so as to open the scratch, thereby forming a cleavage crack. Subsequently, by vapor deposition or sputtering, a low-reflection coating film (not illustrated) of about 5% is formed on the end face on the light emitting side (the front end face), and a high-reflection coating film (not illustrated) of about 95% is formed on the end face (the rear end face) on the side opposite to the front end face. Next, the chip is cut out in the stripe direction of the ridge 30. In such a manner, the semiconductor laser 1 of the embodiment is manufactured.

Next, the operation and effect of the semiconductor laser 1 of the embodiment will be described.

In the semiconductor laser 1 of the embodiment, when a predetermined voltage is applied across the p-side electrode 31 and the n-side electrode 32, the current confined by the ridge 30 is injected to the active layer 23, and light is generated by electron-hole recombination. The light is reflected by the pair of end faces, laser oscillation occurs at a predetermined wavelength, and the light is emitted as a laser beam from the front end face to the outside.

In the embodiment, the low-refractive-index layer 28 having a refractive index lower than that of the second p-type cladding layer 27 is provided between the second p-type cladding layer 27 and the contact layer 29. With the configuration, the light distribution may be prevented from being extended to the contact layer 29 by the low-refractive-index layer 28. Since light absorption by the contact layer 29 may be reduced, without thickening the second p-type cladding layer 27, the internal loss of light may be reduced. As a result, light extraction efficiency may be increased, and high output may be obtained.

Generally, a quaternary material has thermal resistance higher than that of a ternary material. Consequently, in the case of driving the semiconductor laser made of a quaternary material at high power, the temperature of the device rises, and a disadvantage such as output drop may occur. In the embodiment, also in the case where the second p-type cladding layer 27 contains a p-type (AlₜGa₁₋ₜ)ᵤIn₁₋ᵤP (0<t<p, 0<u<1), a disadvantage such as output drop due to thermal resistance may occur. However, in the embodiment, the low-refractive-index layer 28 is provided between the second p-type cladding layer 27 and the contact layer 29. With the configuration, for example, in the case where the thickness of the low-refractive-index layer 28 is set to 0.1 μm to 0.5 μm both inclusive, total thickness of the second p-type cladding layer 27 and the low-refractive-index layer 28 may be made smaller than the thickness of the second p-type cladding layer 27 in the existing structure having no low-refractive-index layer 28 (refer to FIGS. 3 and 4). As a result, the possibility of occurrence of a disadvantage such as output drop due to high thermal resistance may be reduced. In the embodiment, in the case where the thickness of the low-refractive-index layer 28 is set to 0.1 μm to 0.5 μm both inclusive, crystal growth time in a manufacturing process may be made shorter than that in an existing structure having no low-refractive-index layer 28. Thus, productivity may be also improved.

### Modification of First Embodiment

Modification 1

Although the refractive index of the first p-type cladding layer 25 and that of the second p-type cladding layer 27 are different from each other in the foregoing embodiment, they may be equal to each other. Further, the refractive index of the first p-type cladding layer 25 and the second p-type cladding layer 27 may be equal to that of the n-type cladding layer 21.

Modification 2

Although the forbidden band width of the first p-type cladding layer 25 and that of the second p-type cladding layer 27 are different from each other in the foregoing embodiment, they may be equal to each other. The forbidden band width of the first p-type cladding layer 25 and the second p-type cladding layer 27 may be equal to that of the n-type cladding layer 21.

Modification 3

Although the upper end of the valence band of the first p-type cladding layer 25 and that of the valence band of the second p-type cladding layer 27 are different from each other in the foregoing embodiment, they may be equal to each other. Further, as illustrated in FIG. 5, the lower end of the conduction band of the first p-type cladding layer 25 and that of the second p-type cladding layer 27 may be equal to each other.

In the embodiment, the first p-type cladding layer 25 and the second p-type cladding layer 27 may be made of the same material (the same composition ratio). Further, the first p-type cladding layer 25 and the second p-type cladding layer 27 may be made of the same material (the same composition ratio) as that of the n-type cladding layer 21.

Modification 4

In the foregoing embodiment or its modifications, for example, as illustrated in FIGS. 6 and 7, the semiconductor layer 20 may have a low-refractive-index layer 33 (second low-refractive-index layer) whose refractive index is lower than that of the n-type cladding layer 21 between the substrate 10 and the n-type cladding layer 21. The low-refractive-index layer 33 may be in contact with the substrate 10 directly or with a semiconductor layer made of the same material as that of the n-type cladding layer 21 and thinner than the n-type cladding layer 21 in between.

The forbidden band width of the low-refractive-index layer 33 is larger than that of the active layer 23 and the n-side guide layer 22, and larger than that of the n-type cladding layer 21. The refractive index of the low-refractive-index layer 33 is smaller than that of the active layer 23 and the n-side guide layer 22. The lower end of the conduction band of the low-refractive-index layer 33 is higher than that of the conduction band of the active layer 23 and the n-side guide layer 22 and is also higher than that of the conduction band of the n-type cladding layer 21. The low-refractive-index layer 33 contains, for example, n-type (Al_{g}Ga_{1-g})ₕIn₁₋ₕP (0.7≦g≦1, 0<h<1).

With the configuration, the light distribution may be prevented from being extended to the substrate 10 by the low-refractive-index layer 33. Consequently, light absorption in the substrate 10 may be reduced, so that the light internal loss may be reduced without thickening the n-type cladding layer 21.

In the modification, for example, when the thickness of the low-refractive-index layer 33 is set to 0.1 μm to 0.5 μm both inclusive, total thickness of the n-type cladding layer 21 and the low-refractive-index layer 33 may be made smaller than the thickness of the n-type cladding layer 21 in the existing structure having no low-refractive-index layer 33. As a result, the possibility of occurrence of a disadvantage such as output drop due to high thermal resistance may be reduced. In the modification, in the case where the thickness of the low-refractive-index layer 33 is set to 0.1 μm to 0.5 μm both inclusive, crystal growth time in a manufacturing process may be made shorter than that in an existing structure having no low-refractive-index layer 33. Thus, productivity may be also improved.

### Second Embodiment

FIG. 8 illustrates an example of a sectional configuration of a semiconductor laser 2 according to a second embodiment of the invention. FIG. 9 illustrates an example of lineup of conduction bands of the semiconductor laser 2 of FIG. 8. Like the semiconductor laser 1 of the first embodiment, the semiconductor laser 2 of the embodiment is, for example, an edge-emitting type semiconductor laser capable of emitting light in the 600 nm band (for example, 650 nm) for a high-density optical disc such as a recording-type DVD from an end face (not illustrated).

The semiconductor laser 2 has, for example, the semiconductor layer 20 on the substrate 10. The semiconductor laser 2 does not have the low-refractive-index layer 28 between the second p-type cladding layer 27 and the contact layer 29 but has the low-refractive-index layer 33 (second low-refractive-index layer) whose refractive index is lower than that of the n-type cladding layer 21 between the substrate 10 and the n-type cladding layer 21. With respect to the above point, the semiconductor laser 2 is different from the semiconductor laser 1 of the first embodiment.

The forbidden band width of the low-refractive-index layer 33 is larger than that of the active layer 23 and the n-side guide layer 22, and larger than that of the n-type cladding layer 21. The refractive index of the low-refractive-index layer 33 is smaller than that of the active layer 23 and the n-side guide layer 22. The lower end of the conduction band of the low-refractive-index layer 33 is higher than that of the conduction band of the active layer 23 and the n-side guide layer 22 and is also higher than that of the conduction band of the n-type cladding layer 21. The low-refractive-index layer 33 contains, for example, n-type (Al_{g}Ga_{1-g})ₕIn₁₋ₕP (0.7≦g≦1, 0<h<1).

The low-refractive-index layer 33 may be in contact with the substrate 10 directly or with a semiconductor layer made of the same material as that of the n-type cladding layer 21 and thinner than the n-type cladding layer 21 in between.

With the configuration, the light distribution may be prevented from being extended to the substrate 10 by the low-refractive-index layer 33. Consequently, light absorption in the substrate 10 may be reduced, so that the light internal loss may be reduced without thickening the n-type cladding layer 21.

In the embodiment, for example, when the thickness of the low-refractive-index layer 33 is set to 0.1 μm to 0.5 μm, total thickness of the n-type cladding layer 21 and the low-refractive-index layer 33 may be made smaller than the thickness of the n-type cladding layer 21 in the existing structure having no low-refractive-index layer 33. As a result, the possibility of occurrence of a disadvantage such as output drop due to high thermal resistance may be reduced. In the embodiment, in the case where the thickness of the low-refractive-index layer 33 is set to 0.1 μm to 0.5 μm both inclusive, crystal growth time in a manufacturing process may be made shorter than that in an existing structure having no low-refractive-index layer 33. Thus, productivity may be also improved.

Although the invention has been described above by the embodiments, the invention is not limited to the foregoing embodiments but may be variously modified.

For example, in the embodiment, the case where one ridge 30 is provided for the semiconductor laser 1 has been described. Obviously, the invention is also applicable to the case where a plurality of ridges 30 are provided.

Although the invention has been described using the AlGaInP-based compound semiconductor laser as an example in the foregoing embodiments, the invention is also applicable to other high-power compound semiconductor lasers.

The present application contains subject matter related to that disclosed in Japanese Priority Patent Application JP 2009-127838 filed in the Japan Patent Office on May 27, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor laser comprising a semiconductor layer on a semiconductor substrate,
wherein the semiconductor layer has, in order from the semiconductor substrate side, a lower cladding layer, an active layer, an upper cladding layer, and a contact layer, and has a first low-refractive-index layer having a refractive index lower than that of the upper cladding layer between the upper cladding layer and the contact layer.

2. The semiconductor laser according to claim 1, wherein the semiconductor layer contains (AlₓGa₁₋ₓ)_{y}In_{1-y}P (0≦x≦1, 0<y<1).

3. The semiconductor laser according to claim 2, wherein the upper cladding layer contains (AlₐGa₁₋ₐ)_{b}In_{1-b}P (0<a<0.7, 0<b<1), and
the first low-refractive-index layer contains (Al_{c}Ga_{1-c})_{d}In_{1-d}P (0.7≦c≦1, 0<d<1).

4. The semiconductor laser according to claim 3, wherein a thickness of the first low-refractive-index layer is 0.1 μm to 0.5 μm both inclusive.

5. The semiconductor laser according to claim 1, wherein the upper cladding layer has a first cladding layer on the active layer side and has a second cladding layer on the first low-refractive-index layer side, and
refractive index of the first cladding layer is larger than that of the second cladding layer.

6. The semiconductor laser according to claim 1, wherein refractive index of the lower cladding layer and that of the upper cladding layer are equal to each other.

7. The semiconductor laser according to claim 1, wherein the semiconductor layer has a second low-refractive-index layer having a refractive index lower than that of the lower cladding layer between the lower cladding layer and the semiconductor substrate.

8. The semiconductor laser according to claim 7, wherein the lower cladding layer contains (AlₑGa₁₋ₑ)_{f}In_{1-f}P (0<e<0.7, 0<f<1), and
the second low-refractive-index layer contains (Al_{g}Ga_{1-g})ₕIn₁₋ₕP (0.7≦g≦1, 0<h<1).

9. The semiconductor laser according to claim 7, wherein thickness of the second low-refractive-index layer is 0.1 μm to 0.5 μm both inclusive.

10. A semiconductor laser comprising a semiconductor layer on a semiconductor substrate,
wherein the semiconductor layer has, in order from the semiconductor substrate side, a lower cladding layer, an active layer, an upper cladding layer, and a contact layer, and has a second low-refractive-index layer having a refractive index lower than that of the lower cladding layer between the lower cladding layer and the semiconductor substrate.
